(19) United States
(12) Patent Application Publication
(10) Pub. No.: US 2026/0212078 A1
(43) Pub. Date: Jul. 23, 2026

(54) SYSTEMS AND METHODS FOR BROAD NEURAL NETWORKS AND SENSING ARRAY MEASUREMENT ESTIMATION

(71) Applicant: NXP USA, Inc., AUSTIN, TX (US)

(72) Inventors: Ryan Haoyun Wu, San Jose, CA (US); Binbin Shi, Boston, MA (US); Satish Ravindran, Fremont, CA (US); Jun Li, San Jose, CA (US); Lifan Xu, Tuscaloosa, AL (US)

(21) Appl. No.: 19/035,629

(22) Filed: Jan. 23, 2025

(51) Int. Cl. G06F 30/27

(52) U.S. Cl. CPC G06F 30/27

(57) ABSTRACT

A Broad Neural Network (BNN) may be used to model a full sensing array. A sensing array may produce a first vector that includes P measurements. The full sensing array may be modeled by using the first vector to produce a second vector that includes Q wave domain measurements, as follows. The first vector may be multiplied by interpolation matrices to produce interpolated vectors that each include Q interpolated values. Applying a transform function to the interpolated vectors produces representation vectors that may be interleaved to produce Q pooling inputs. The second vector can be produced by performing a plurality of nonlinear pooling operations on the Q pooling inputs, wherein one of the nonlinear pooling operations produces one of the Q wave domain measurements in the second vector from one of the Q pooling inputs. The interpolation matrices may be produced by training the BNN.

### TECHNICAL FIELD

The systems and methods relate to sensors, sensing arrays, RADAR arrays, signal processing, RADAR signal processing, signal estimation, RADAR array modeling, machine learning, gradient descent algorithms, and backpropagation. More specifically, the systems and methods relate to using machine learning algorithms to use the measurements from a sparse sensing array to estimate the measurements produced by a dense sensing array.

### BACKGROUND

Radar sensing arrays are crucial in vehicles for achieving four-dimensional detection such as capturing range, Doppler, azimuth, and elevation angles. These sensing arrays are valued for their affordability and ability to perform under adverse conditions. To enhance resolution in the angle domain, multiple-input multiple-output (MIMO) radar systems utilize large-sized virtual arrays. These arrays are designed to improve angle resolution through a sparse configuration of TX and RX antennas, which increases the size of the virtual aperture without needing a large number of transceivers. However, this sparse configuration can result in high sidelobes in the angle spectrum resulting in a higher false alarm rate. In automotive radars, there are several approaches to solve the sparse array angle estimation problem. In some examples, four-dimension detection may be achieved by directly processing sparse array measurements via techniques such as compressive sensing, iterative adaptive approaches, and neural networks. Other examples may interpolate sparse array measurements into dense array measurements via techniques such as transformation matrices, matrix completion, and neural networks. Systems and methods that produce more accurate results are needed.

### BRIEF SUMMARY OF SOME EXAMPLES

The following presents a summary of one or more aspects of the present disclosure, in order to provide a basic understanding of such aspects. This summary is not an extensive overview of all contemplated features of the disclosure and is intended neither to identify key or critical elements of all aspects of the disclosure nor to delineate the scope of any or all aspects of the disclosure. Its sole purpose is to present some concepts of one or more aspects of the disclosure as a prelude to the more detailed description presented later.

An aspect of the subject matter described in this disclosure can be implemented by a system. The system can include a memory configured to store a plurality of interpolation matrices, and a processor configured to model a full sensing array by producing a second vector that includes Q wave domain measurements in response to receiving a first vector that includes P measurements produced by a sensing array, wherein producing the second vector includes multiplying the first vector by the interpolation matrices to produce a plurality of interpolated vectors that each include Q interpolated values, producing a plurality of representation vectors by applying a transform function to the interpolated vectors, interleaving the representation vectors to produce Q pooling inputs, and producing the second vector by performing a plurality of nonlinear pooling operations on the Q pooling inputs, wherein one of the nonlinear pooling operations produces one of the Q wave domain measurements in the second vector from one of the Q pooling inputs.

Another aspect of the subject matter described in this disclosure can be implemented by a method that models a full sensing array by producing a second vector that includes Q wave domain measurements in response to receiving a first vector that includes P measurements produced by a sensing array. The method can include storing a plurality of interpolation matrices, multiplying the first vector by the interpolation matrices to produce a plurality of interpolated vectors that each include Q interpolated values, producing a plurality of representation vectors by applying a transform function to the interpolated vectors, interleaving the representation vectors to produce Q pooling inputs, and producing the second vector by performing a plurality of nonlinear pooling operations on the Q pooling inputs, wherein one of the nonlinear pooling operations produces one of the Q wave domain measurements in the second vector from one of the Q pooling inputs.

Yet another aspect of the subject matter described in this disclosure can be implemented by a system. The system can include a memory configured to store a plurality of transformative matrices, and a processor configured to model a full sensing array by producing a second vector that includes Q wave domain measurements in response to receiving a first vector that includes P measurements produced by a sensing array, wherein producing the second vector includes multiplying the first vector by the transformative matrices to produce a plurality of representation vectors, interleaving the representation vectors to produce Q pooling inputs, and producing the second vector by performing a plurality of nonlinear pooling operations on the Q pooling inputs, wherein one of the nonlinear pooling operations produces one of the Q wave domain measurements in the second vector from one of the Q pooling inputs.

In some implementations of the methods and devices, an ith one of the Q pooling inputs includes an ith element of each of the representation vectors. In some implementations of the methods and devices, each of the representation vectors is normalized before the Q pooling inputs are produced. In some implementations of the methods and devices, the plurality of interpolation matrices includes B interpolation matrices, the plurality of interpolated vectors includes B interpolated vectors produced by multiplying the first vector by each of the B interpolation matrices, and the plurality of representation vectors includes B representation vectors produced by applying the transform function to the B interpolation matrices. In some implementations of the methods and devices, the transform function is a discrete Fourier transform. In some implementations of the methods and devices, the transform function is a linear transform.

In some implementations of the methods and devices, the one of the Q pooling inputs includes a plurality of wave domain values, and the one of the nonlinear pooling operations selects the one of the wave domain values having a smallest absolute magnitude as the one of the Q wave domain measurements. In some implementations of the methods and devices, the processor is further configured to model the full sensing array by producing an estimated full array output that includes the P measurements and that includes at least one of a plurality of estimated measurements by producing the plurality of estimated measurements by applying an inverse transform function to the Q wave domain measurements, identifying P of the estimated measurements that correspond to the P measurements, and producing the estimated full array output, the estimated full array output including the P measurements, at least one of the estimated measurements, and none of the P of the estimated measurements that correspond to the P measurements. In some implementations of the methods and devices, a plurality of simulations of the full sensing array produces a plurality of desired array outputs that are used to produce a plurality of desired second vectors, the desired array outputs are used to produce a plurality of simulated first vectors that are used to produce a plurality of simulated second vectors, and the interpolation matrices are produced by minimizing a plurality of errors between the desired second vectors and the simulated second vectors.

In some implementations of the methods and devices, the method may further include producing a plurality of estimated measurements by applying an inverse transform function to the Q wave domain measurements, identifying P of the estimated measurements that correspond to the P measurements, and producing an estimated full array output of the full sensing array, the estimated full array output including the P measurements, at least one of the estimated measurements, and none of the P of the estimated measurements that correspond to the P measurements.

In some implementations of the methods and devices, each one of the transformative matrices is a linear product of one of a plurality of interpolation matrices and a linear transform matrix. In some implementations of the methods and devices, the linear transform matrix is a discrete Fourier transform matrix. In some implementations of the methods and devices, multiplying the transformative matrices by an inverse linear transform matrix produces a plurality of interpolation matrices. In some implementations of the methods and devices, a plurality of simulations of the full sensing array produces a plurality of desired array outputs that are used to produce a plurality of desired second vectors, the desired array outputs are used to produce a plurality of simulated first vectors that are used to produce a plurality of simulated second vectors, a plurality of interpolation matrices is produced by minimizing a plurality of errors between the desired second vectors and the simulated second vectors, and the transformative matrices are produced by multiplying the plurality of interpolation matrices by a linear transform matrix.

These and other aspects will become more fully understood upon a review of the detailed description, which follows. Other aspects and features will become apparent to those of ordinary skill in the art, upon reviewing the following description of specific examples in conjunction with the accompanying figures. While features may be discussed relative to certain examples and figures below, any example may include one or more of the advantageous features discussed herein. In other words, while one or more examples may be discussed as having certain advantageous features, one or more of such features may also be used in accordance with the examples discussed herein. In similar fashion, while the examples may be discussed below as devices, systems, or methods, the examples may be implemented in various devices, systems, and methods.

### BRIEF DESCRIPTION OF THE DRAWINGS

FIG. 1A is a high-level diagram illustrating an example of a full sensing array configured to produce a full array output that includes Q measurements, according to some aspects.

FIG. 1B is a high-level diagram illustrating an example of a sensing array configured to produce a first vector that includes P measurements, according to some aspects.

FIG. 2A is a high-level diagram illustrating an example of a Broad Neural Network (BNN) configured to produce an estimated full array output in response to receiving P measurements from a sensing array, according to some aspects.

FIG. 2B is a high-level conceptual diagram of a BNN, according to some aspects.

FIG. 3 is a high-level block diagram illustrating an example of a host machine that may implement a BNN, according to some aspects.

FIG. 4 is a high-level conceptual diagram of a software system configured to implement a BNN, according to some aspects.

FIG. 5 is a high-level conceptual diagram of an interleaver 203 performing a nonlinear pooling operation, according to some aspects.

FIG. 6 is a high-level conceptual diagram of a backfiller, according to some aspects.

FIG. 7 is a high-level conceptual diagram illustrating an example of normalizing a vector, according to some aspects.

FIG. 8 is a high-level conceptual diagram illustrating an example of a min-pool nonlinear pooling operation, according to some aspects.

FIG. 9 is a diagram illustrating a graph of an example of predicted target locations relative to actual target locations and to target locations measured by dense and sparse sensing arrays, according to some aspects.

FIG. 10 is a zoomed in version of FIG. 9, according to some aspects.

FIG. 11 is a high-level flow diagram illustrating an example of producing a library of desired array outputs that may be used for training a BNN, according to some aspects.

FIG. 12 is a high-level flow diagram illustrating an example of training a BNN that produces a full array output in response to receiving a first vector, according to some aspects.

FIG. 13 is a high-level flow diagram illustrating an example of training a BNN that produces a wave domain estimate in response to receiving a first vector, according to some aspects.

FIG. 14 is a diagram illustrating an example of a loss function that may be used to calculate an error between two vectors, according to some aspects.

FIG. 15 is a high-level diagram illustrating an example of a multi-layer BNN configured to produce an estimated full array output in response to receiving P measurements from a sensing array, according to some aspects.

FIG. 16 is a diagram illustrating the training error with respect to different α settings of an iterative backfilling BNN having four layers, according to some aspects.

FIG. 17 is a high-level flow diagram illustrating an example of a method that models a full sensing array by producing a second vector that includes Q wave domain measurements in response to receiving a first vector that includes P measurements produced by a sensing array, according to some aspects.

Throughout the description, similar reference numbers may be used to identify similar elements.

### DETAILED DESCRIPTION

It will be readily understood that the components of the examples as generally described herein and illustrated in the appended figures could be arranged and designed in a wide variety of different configurations. Thus, the following more detailed description of various examples, as represented in the figures, is not intended to limit the scope of the present disclosure but is merely representative of various examples. While the various aspects of the examples are presented in drawings, the drawings are not necessarily drawn to scale unless specifically indicated.

Systems and methods that implement aspects may have various differing forms. The described systems and methods are to be considered in all respects only as illustrative and not restrictive. The scope of the claims is, therefore, indicated by the claims themselves rather than by this detailed description. All changes which come within the meaning and range of equivalency of the claims are to be embraced within their scope.

Reference throughout this specification to features, advantages, or similar language does not imply that any system or method implements each and every aspect that may be realized. Rather, language referring to the features and advantages is understood to mean that a specific feature, advantage, or characteristic described in an example may be implemented in or by at least one example. Thus, discussions of the features and advantages, and similar language, throughout this specification may, but do not necessarily, refer to the same example.

Furthermore, the described features, advantages, characteristics, and aspects may be combined in any suitable manner in one or more systems or methods. One skilled in the relevant art will recognize, in light of the description herein, that one example may be practiced without one or more of the specific features or advantages of another example. In other instances, additional features and advantages may be recognized in one example that may not be present in all the examples.

Reference throughout this specification to “one example”, “an example”, or similar language means that a particular feature, structure, or characteristic described in connection with the indicated example is included in at least one example. Thus, the phrases “in one example”, “in an example”, and similar language throughout this specification may, but do not necessarily, all refer to the same example.

Radar sensors are crucial in vehicles for achieving four-dimensional detection capturing range, Doppler, azimuth, and elevation angles. To enhance resolution in the angle domain, multiple-input multiple-output (MIMO) radar systems utilize large-sized virtual arrays. Sparse sensing arrays are designed to improve angle resolution through a sparse configuration of TX and RX antennas, which may increase the size of the virtual aperture without needing a large number of transceivers. However, sparse sensing arrays may have high sidelobes in the angle spectrum resulting in a high false alarm rate.

Some automotive radar systems use deep neural networks (DNNs) for solving the angle finding problem of sparse sensing arrays. Such DNNs process inputs through multiple layers of linear and nonlinear operations to generate desired inferencing results. Typically, DNN performance depends on the neural network's regression capability, which scales with the network's depth and is influenced by the nonlinear characteristics of its activation functions. In general, a deeper neural net allows the model to learn more complex patterns and dependencies such that better performance can be obtained. However, deeper networks can lead to inefficiencies due to the increased computational burden and latency due to layered dependency. As the number of layers increases, inefficiency is also found in the repeated operations of the same activation function. Additionally, many commonly used activation functions are sensitive to numerical precision such that DNN inferencing models require hardware capable of high numerical precision. What is needed is a new neural net architecture that does not require deep layers and does not require delicate activation functions.

A broad neural network (BNN) does not have the drawbacks of other machine learning models such as DNNs. A BNN may have a simple activation function (e.g., min pooling) and excellent results may be obtained from a single layer BNN that has far less latency and computational complexity than a DNN. Note that the acronym BNN is used herein for “Broad Neural Network” and not for the quite different “Bayesian Neural Network”.

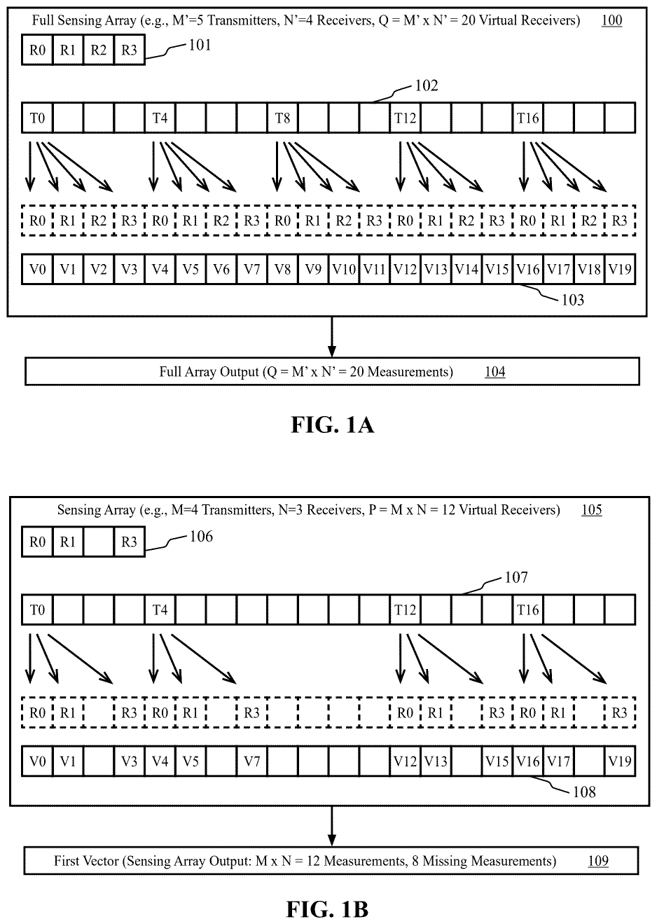

FIG. 1A is a high-level diagram illustrating an example of a full sensing array 100 configured to produce a full array output that includes Q measurements, according to some aspects. The full sensing array 100 includes a receiver array 101 and a transmitter array 102. The receiver array 101 has N′=4 receivers and the transmitter array 102 has M′=5 transmitters. The transmitters may transmit signals (e.g., RADAR signals) that are received by the receivers. The transmitted and received signals may have a wavelength, λ. FIG. 1A indicates the relative positions of the receivers in the receiver array 101 and the relative positions of the transmitters in the transmitter array 102. The receivers are numbered in a manner that indicates their relative positions. Receiver R0 is at position 0, receiver R1 is at position 1, etc. The differences between the numbers may indicate the relative positions of the receivers. For example, the distance between RA and RB may equal (B-A) times half the wavelength. As such, the distance between R0 and R1 may equal half the wavelength while the distance between R1 and R3 may equal the wavelength. The transmitters are similarly numbered. For example, the distance between T8 and T0 may equal four times the wavelength. In some examples, receiver positions and transmitter positions may coincide (e.g., RA and TA are at the same position). In other examples, receiver positions and transmitter positions may not coincide (e.g., RA and TA are at different positions). Each receiver may receive each signal transmitted by each transmitter. Each receiver-transmitter pair may therefore define a virtual receiver that is located at the receiver's position plus the transmitter's position. As such, transmitter A and receiver B may define virtual receiver A+B (e.g., T0 and R0 define V0, T4 and R1 define V5, etc.). The numbers of the virtual receivers may indicate their positions relative to one another in a virtual sensor array 103. For example, V6 may be 3 wavelengths from V0 and from V12. A virtual sensing array 103 may produce a measurement for each virtual receiver. For example, the receiver-transmitter pair R2 and T4 define virtual receiver V6. As such, the measurement corresponding to V6 may be R2's measurement of T4's signal. In the example illustrated in FIG. 1A, the full sensing array has Q virtual receivers where Q =M′×N′=5×4=20. The full sensing array may be called a dense sensing array because there is a virtual receiver at every half wavelength step between V0 and V19. The full sensing array 100 may produce a full array output 104 that includes Q measurements corresponding to the Q virtual receivers 103 of the full sensing array 100.

FIG. 1B is a high-level diagram illustrating an example of a sensing array 105 configured to produce a first vector that includes P measurements, according to some aspects. Removing receivers and transmitters from a full sensing array results in a sensing array that is not full or dense. As such, removing R2 and T8 from the full sensing array 100 illustrated in FIG. 1A results in the sensing array 105 illustrated in FIG. 1B. The sensing array 105 has a receiver array 106 that includes N=3 receivers. The sensing array 105 has a transmitter array 107 that includes M=4 transmitters. Each receiver-transmitter pair defines a virtual receiver in a virtual receiver array 108. The virtual receiver array 108 has P=M×N=12 virtual receivers corresponding to the P receiver-transmitter pairs of the sensing array. As can be seen, the virtual receiver array 108 of the sensing array 105 includes P of the virtual receivers that are in the virtual receiver array 103 of the full sensing array 100. The sensing array 105 may produce a first vector 109 that includes P measurements corresponding to the P virtual receivers 108 of the sensing array 105.

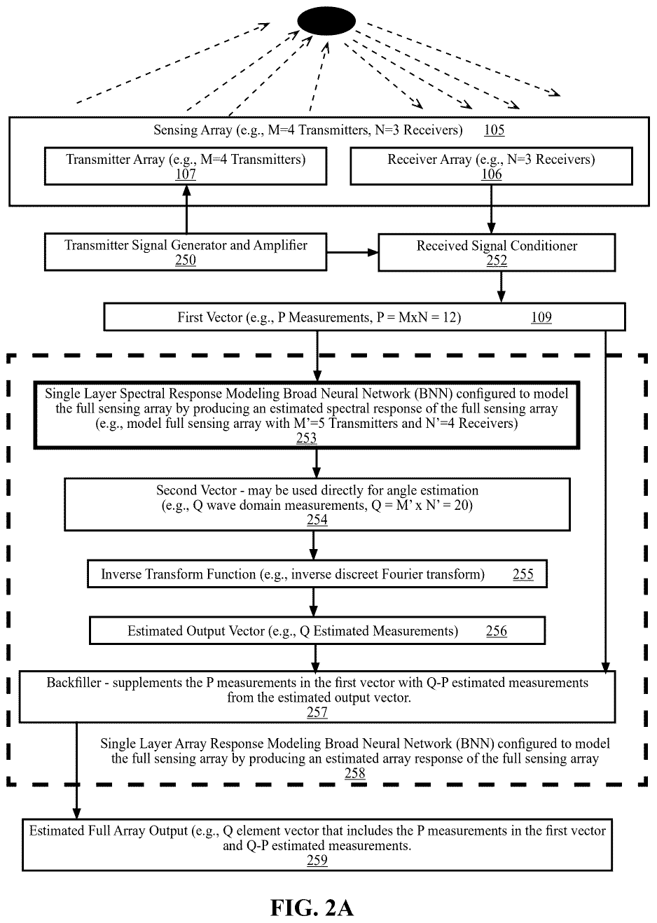

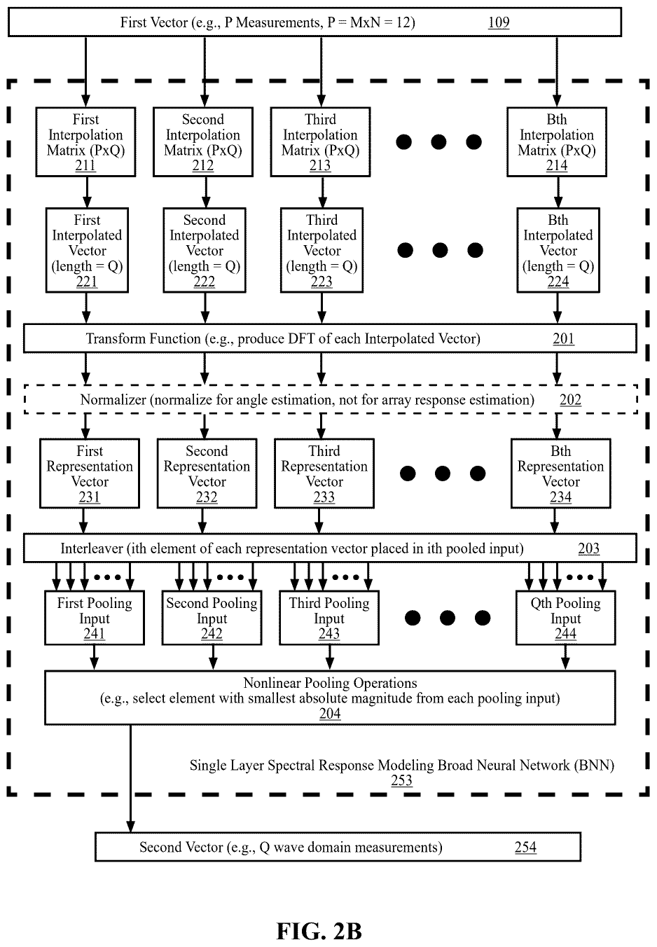

FIG. 2A is a high-level diagram illustrating an example of a Broad Neural Network (BNN) configured to produce an estimated full array output 259 in response to receiving P measurements from a sensing array, according to some aspects. A sensing array 105 may be a sparse array having M transmitters in a transmitter array 107 and N receivers in a receiver array 106. A transmitter signal generator and amplifier 250 may produce four different signals that may each be transmitted by one of the four different transmitters in the transmitter array 107. The four transmitted signals may be reflected by one or more targets. The reflected signals may be received by the three receivers in the receiver array 106. As such, there are P=M×N=3×4=12 virtual receivers corresponding to the 12 transmitter-receiver pairs. The received signals may be processed by a received signal conditioner 252 that may produce a first vector 109 that includes P measurements, each of the P measurements corresponding to one of the 12 transmitter-receiver pairs. The measurements may include amplitude and phase. As such, the measurements may be represented by complex numbers. Those practiced in the art of multiple-in multiple-out sensing arrays are familiar with numerous techniques for obtaining P measurements from sensing arrays that have P transmitter-receiver pairs.

The BNN shown in FIG. 2A is configured to model the full sensing array by producing a Q=20 element output vector in response to receiving the P=12 element first vector 109. FIG. 2A has a single layer spectral response modeling BNN 253 inside of a single layer array response modeling BNN 258. The single layer spectral response modeling BNN 253 (see FIG. 2B) produces a second vector in response to receiving the first vector 109. In some examples, the single layer spectral response modeling BNN 253 includes a normalization step such that the second vector 254 is normalized and may be used directly for angle estimation because it is an estimate of the spectral response of the full sensing array. In other examples, the single layer spectral response modeling BNN 253 does not include a normalization step such that the second vector 254 may be used to estimate the array response of the full sensing array.

An estimate of the full sensing array's response may be estimated by further processing of the second vector 254. An estimated output vector 256 may be produced by applying an inverse transform function 255 to the second vector 254. The estimated output vector may include Q estimated measurements corresponding to the Q transmitter-receiver pairs in the full sensing array. The inverse transform function 255 may be the inverse of a transform function 201 that is in the single layer spectral response modeling BNN 253. For example, the transform function may be a discrete Fourier transform (DFT), and the inverse transform function may be an inverse DFT (IDFT). The estimated full array output 259 may be produced by a backfiller 257 that may supplement the P measurements in the first vector with Q-P of estimated measurements in the estimated output vector 256. In the example illustrated in FIG. 2A, the full sensing array has 20 virtual receivers and the sensing array 105 has 12 virtual receivers. As such, the estimated output vector 256 includes 12 estimated measurements corresponding to the 12 transmitter-receiver pairs in the sensing array 105. The backfiller may produce the estimated full array output 259 by replacing those 12 estimated measurements with the 12 measurements in the first vector. As such, the estimated full array output 259 may include the M measurements in the first vector, at least one of the estimated measurements in the estimated output vector 256 (e.g., Q−P estimated measurements), and none of the P of the estimated measurements that correspond to the P measurements in the first vector.

FIG. 2B is a high-level conceptual diagram of a BNN, according to some aspects. More specifically, FIG. 2B illustrates the single layer spectral response modeling broad neural network (BNN) 253 introduced in FIG. 1. For brevity, “BNN” may be used herein for any of the neural networks that include a single layer spectral response modeling BNN. The BNN 253 is configured to produce a second vector 254 (e.g., Q wave domain measurements) in response to receiving a first vector 109 (e.g., P measurements from a sensing array where Q>P). The BNN includes B interpolation matrices. For visualization of the architecture, “B” may be considered to indicate the breadth of the BNN. The first vector 109 is multiplied by each of the interpolation vectors to produce B interpolated vectors. For example, the first vector 109 may be multiplied by the first interpolation matrix 211 to produce the first interpolated vector 221, may be multiplied by the second interpolation matrix 212 to produce the second interpolated vector 222, may be multiplied by the third interpolation matrix 213 to produce the third interpolated vector 223, and may be multiplied by the Bth interpolation matrix 214 to produce the Bth interpolated vector 224. The interpolation matrices are P×Q matrices such that the interpolated vectors have length=Q. As such, each interpolated vector includes Q interpolated values.

A transform function 201 may be applied to the interpolated vectors to produce representation vectors. The transform function 201 may be a linear transform (e.g., discrete Fourier transform, discrete cosine transform, etc.). In an example, a transformer may produce a first representation vector 231 by applying the transform function 201 to the first interpolated vector 221, may produce a second representation vector 232 by applying the transform function 201 to the second interpolated vector 222, may produce a third representation vector 233 by applying the transform function 201 to the third interpolated vector 223, and may produce a Bth representation vector 234 by applying the transform function 201 to the Bth interpolated vector 224. Each representation vector may include Q wave domain values. The wave domain values may be representative of the amplitudes of sinusoids (e.g., for DFT, discrete cosine transform, etc.) or of other basis functions (wavelet transform, etc.). In many RADAR examples, the DFT is used because the output of the DFT has a physical meaning, specifically the spectral response of the sensing array. Those practiced in signal processing know of various fast algorithms for computing certain linear transforms such as the fast Fourier transform (FFT) for calculating the DFT, the inverse FFT (IFFT) for calculating the IDFT, etc.

A spectrum or wave domain representation of a vector may be produced by multiplying the vector by a discrete Fourier transform matrix that has different frequency sinusoids in each row of the matrix. The vector may be recovered by multiplying its wave domain representation by an inverse discrete Fourier transform matrix. The DFT matrix and the IDFT matrix are linear transform matrices that are inverses of one another. In other words, the DFT matrix may be considered a forward linear transform matrix and the IDFT may be considered an inverse linear transform matrix. Those familiar with linear algebra are familiar with such transform matrices and linear transform matrices. As such, applying the transform function 201 to a Q length vector may be equivalent to multiplying the Q length vector by a Q×Q transform matrix. In practice, a fast algorithm such as an FFT or IFFT may be used to apply the transform function (see transform function 201 of FIG. 2) or the inverse transform function (see inverse transform function 255 of FIG. 1).

Machine learning models, such as a BNN, may have a training phase and an inferencing phase. During training, various training algorithms adapt the machine learning model to perform a specific function. After training the machine learning model may be deployed as a trained model that can be used for inferencing. During inferencing, the machine learning model performs the specific function. As an example, a supercomputer cluster may be required to train the machine learning model whereas a microcontroller may be sufficient for running the machine learning model in inferencing mode.

Training the BNN requires that the interpolation matrices be updated by a training algorithm (e.g., gradient descent, backpropagation, etc.). During inferencing, however, the interpolation matrices may be unchanging. Similarly, the transform function may be unchanging. As such, multiplying the first vector by the interpolation matrices may be combined with applying the transform function to the interpolated vectors when the applying the transform function is equivalent to matrix multiplication. Some examples may therefore use transformative matrices during inferencing. A transformative matrix is a P×Q matrix that is the linear product of a P×Q interpolation matrix and a Q×Q transform matrix. A linear product may be the result of matrix multiplication. As such, a transformative matrix may be the result of performing a matrix multiplication of an interpolation matrix by a transform matrix. Multiplying the first vector 109 by a transformative matrix therefore produces a representation vector. The transformative matrices may therefore replace both the interpolation matrices and the transform function during inferencing. A BNN that multiplies the first vector by B transformative matrices during inferencing may be equivalent to a BNN that multiplies the first vector by B interpolation matrices and that applies a transform function to the interpolated vectors.

Some examples may use a normalizer 202 that normalizes the representation vectors. In an example, each representation vector is normalized such that every element in the vector is divided by the magnitude of the element with the highest magnitude. As such, every element in every vector has a magnitude less than or equal to 1. A further step in the normalization may be to remove the phase information such that the representation vector only indicates magnitude (in some case squared magnitude). A normalized representation vector is useful when the second vector 254 is to be used directly for angle estimation. Examples in which the second vector is used to produce an estimated full array output 259 may omit the normalizer 202.

An interleaver 203 may interleave the representation vectors to produce pooling inputs. There are Q pooling inputs and the interleaver may place the ith element of each representation vector into the ith pooling input. As such, each pooling input includes B elements, one from each of the B representation vectors. In an example, the first pooling input 241 includes the first element of each of the representation vectors, the second pooling input 242 includes the second element of each of the representation vectors, the third pooling input 243 includes the third element of each of the representation vectors, and the Qth pooling input 244 includes the Qth element of each of the representation vectors.

Each of the pooling inputs may be converted into one of the elements in the second vector 254 by nonlinear pooling operations 204. The nonlinear pooling operations 204 serve as the activation function in the BNN. In other architectures, such as DNNs, nearly every matrix multiplication is followed by an activation function. For example, a DNN would apply an activation function to every representation vector, resulting in applying the activation function to B vectors of length Q. The BNN enjoys considerable computational efficiency relative to the DNN because the activation function is applied after the pooling operations, resulting in applying the activation function to a single length Q vector. In an example, the “min-pool” activation function is applied by selecting the smallest magnitude element from each pooling input. For example, the first element of the second vector 254 may be the smallest magnitude element in the first pooling input 241, the second element of the second vector 254 may be the smallest magnitude element in the second pooling input 242, the third element of the second vector 254 may be the smallest magnitude element in the third pooling input 243, and the Qth element of the second vector 254 may be the smallest magnitude element in the Qth pooling input 244. Min pooling is useful because it tends to get rid of the sidelobes and is thereby less likely to report a target in one of the sidelobes.

In other examples, the nonlinear pooling operation may be one of the other pooling operations available in machine learning libraries (e.g., PyTorch, Tensorflow, etc.). In an example, Gumbel min pooling was used with favorable results. One reason for using Gumbel min pooling is that min-pooling is not differentiable which may lead to issues during training because the derivative of the activation function may be used by the training algorithm. In machine learning, “Gumbel min pooling” refers to a technique that leverages the Gumbel distribution to perform a differentiable form of pooling, essentially allowing a neural network to select a subset of features or data points in a way that can be backpropagated through during training, even though the selection process is inherently discrete (like choosing only a few elements from a set)

FIG. 3 is a high-level block diagram illustrating an example of a host machine that may implement a BNN, according to some aspects. A computing device in the form of a host machine 301 configured to interface with controllers, peripheral devices, and other elements may include one or more processors 314 coupled to memory 302, removable storage 315, and non-removable storage 316. Memory 302 may include volatile memory 308 and non-volatile memory 309. Host machine 301 may include or have access to a computing environment that includes a variety of transitory and non-transitory computer storage media such as volatile memory 308 and non-volatile memory 309, removable storage 315 and non-removable storage 316. Examples of a computer storage medium include random access memory (RAM), read only memory (ROM), erasable programmable read-only memory (EPROM) and electrically erasable programmable read-only memory (EEPROM), flash memory or other memory technologies, compact disc read-only memory (CD ROM), Digital Versatile Disks (DVD) or other optical disk storage, magnetic cassettes, magnetic tape, magnetic disk storage, or other magnetic storage devices, or any other medium capable of storing computer-readable instructions and data. Of the listed computer storage media, volatile memory, and most RAM, such as dynamic RAM (DRAM), are transitory computer storage media while the others are considered non-transitory computer storage media.

Host machine 301 may include, or have access to, a computing environment that includes input 313, output 311, and a communications subsystem 317. The host machine 301 may operate in a networked environment using the communications subsystem 317 to connect to one or more remote computers, remote sensors and/or controllers, detection devices, hand-held devices, multi-function devices (MFDs), speakers, mobile devices, tablet devices, mobile phones, wireless access points, smartphones, or other such devices. The remote computer may also be a personal computer (PC), server, router, network PC, radio frequency identification (RFID) enabled device, a peer device or other common network node, etc. The communication connection may connect to a local area network (LAN), a wide area network (WAN), wireless network, Bluetooth connection, or other networks.

Output 311 may be provided as a computer monitor or flat panel display but may include any output device. Output 311 and/or input 313 may include a data collection apparatus associated with host machine 301. In addition, input 313, which may include a computer keyboard, a pointing device such as a computer mouse, computer trackpad, or touch screen allows a user to instruct host machine 301. A user interface can be provided using output 311 and input 313. Output 311 may include a display 312 for displaying data and information for a user, or for interactively displaying a graphical user interface (GUI) 310. A GUI is typically responsive to user inputs entered through input 313 and typically displays images and data on display 312.

Note that the term “GUI” generally refers to a type of environment that represents programs, files, options, and so forth by means of graphically displayed icons, menus, and dialog boxes on a computer monitor screen or smartphone screen. A user can interact with the GUI to select and activate such options by directly touching the screen and/or pointing and clicking with a user input device 313 such as, for example, a pointing device such as a mouse, and/or with a keyboard. A particular item can function in the same manner to the user in all applications because the GUI provides standard software routines (e.g., the application module 405 can include program code in executable instructions, including such software routines) to handle these elements and report the user's actions.

Computer-readable instructions (e.g., program code in application code and data 303), can include or be representative of software routines, software subroutines, software objects, etc. described herein, are stored on a computer-readable medium (e.g., non-transitory computer storage media or transitory computer storage media) and are executable by the processor (also called a processing unit) 314 of host machine 301. The application code and data 303 may include computer code and data including, for example, interpolation matrices 320, matrix multiplier 325, linear transformer 326, normalizer 202, interleaver 203, nonlinear pooling operations code 329, backfiller 257, and code for training the BNN. The interpolation matrices 320 may include the first interpolation matrix 211, the second interpolation matrix 212, the third interpolation matrix 213, and the Bth interpolation matrix 214. The computer code may read, write, or modify data. A hard drive, CD-ROM, RAM, flash memory, and a USB drive are just some examples of a computer storage medium.

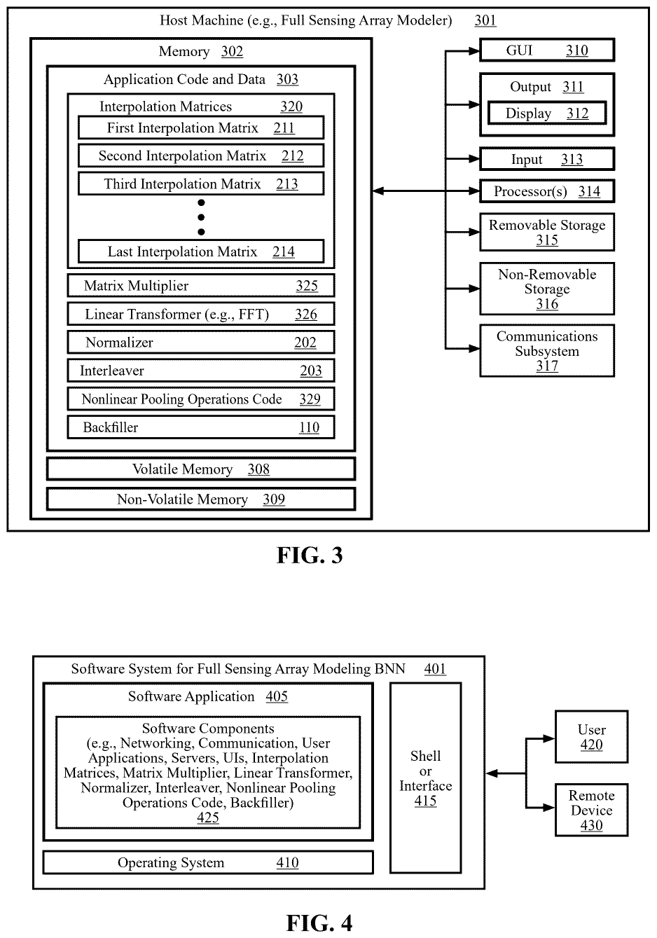

FIG. 4 is a high-level block diagram illustrating an example of a software system 401 according to some aspects. The software system 401 may be employed for directing the operation of data-processing systems such as host machine 301. Software applications 405 may be stored in memory 302, on removable storage 315 or on non-removable storage 316, and generally includes and/or is associated with an operating system 410 and a shell or interface 415. One or more application programs may be “loaded” (i.e., transferred from removable storage 315 or non-removable storage 316 into the memory 302) for execution by the host machine 301. Application programs 405 can include software components 425 such as software modules, software subroutines, software objects, network code, user application code, server code, UI code, container code, virtual machine (VM) code, interpolation matrices, matrix multiplier code, linear transformer code, normalizer code, interleaver code, nonlinear pooling operations code, backfiller code, code for training the BNN, etc. The software system 401 can have multiple software applications each containing software components. The host machine 301 can receive user commands and data through interface 415, which can include input 313, output 311, and communications subsystem 317 accessible by a user 420 or remote device 430. These inputs may then be acted upon by the host machine 301 in accordance with instructions from operating system 410 and/or software applications 405 and any software components 425 thereof. The operating system may include operating system software components such as operating system services, file system handlers, process management, monitoring subsystem, etc.

Generally, software components 425 can include, but are not limited to, routines, subroutines, software applications, programs, modules, objects (used in object-oriented programs), executable instructions, data structures, etc., that perform specific tasks or implement specific abstract data types and instructions. Moreover, those skilled in the art will appreciate that elements of the disclosed methods and systems may be practiced with other computer system configurations such as, for example, hand-held devices, mobile phones, smartphones, tablet devices, multi-processor systems, microcontrollers, printers, copiers, fax machines, multi-function devices, data networks, microprocessor-based or programmable consumer electronics, networked personal computers, minicomputers, mainframe computers, servers, medical equipment, medical devices, etc.

Note that the terms “component” and “module” as utilized herein may refer to one of or a collection of routines and data structures that perform a particular task or implement a particular data type. Applications and components may be composed of two parts: an interface, which lists the constants, data types, variables, and routines that can be accessed by other modules or routines; and an implementation, which is typically private (accessible only from within the application or component) and which includes source code that implements the routines in the application or component. The terms application or component may also simply refer to an application such as a computer program designed to assist in the performance of a specific task such as word processing, accounting, etc. Components can be built or realized as special purpose hardware components designed to equivalently assist in the performance of a task.

The interface 415 can include a graphical user interface 310 that may display results, whereupon a user 420 or remote device 430 may supply additional inputs or terminate a particular session. In some examples, operating system 410 and GUI 310 can be implemented in the context of a “windows” system. It can be appreciated, of course, that other types of systems are possible. For example, rather than a traditional “windows” system, other operating systems such as, for example, a real time operating system (RTOS) more commonly employed in wireless systems may also be employed with respect to operating system 410 and interface 415. The software application 405 can include, for example, software components 425 that may include instructions for conducting steps or logical operations such as those shown and described herein.

The description herein is presented with respect to examples that may be implemented in the context of, or require the use of, a data processing system such as host machine 301, in conjunction with program code in an application code and data 303 stored in memory 302, software system 401, or host machine 301. The disclosed examples, however, are not limited to any specific application or environment. Instead, those skilled in the art will find that the systems and methods described herein may be advantageously applied to a variety of system and application software including database management systems, word processors, etc. Moreover, the examples may be implemented on a variety of different platforms including Windows, Macintosh, UNIX, LINUX, Android, Arduino, etc. Therefore, the descriptions of the examples which follow are for purposes of illustration and not considered a limitation.

Host machine 301 and software system 401 can take the form of or run as virtual machines (VMs) or containers that run on physical machines. A VM or container typically supplies an operating environment, appearing to be an operating system, to program code in an application module and software applications 405 running in the VM or container. A single physical computer can run a collection of VMs and containers. In fact, an entire network data processing system including a multitude of host machines 301, LANs and perhaps even WANs or portions thereof can all be virtualized and running within a single computer (or a few computers) running VMs or containers. Those practiced in cloud computing are practiced in the use of VMs, containers, virtualized networks, and related technologies.

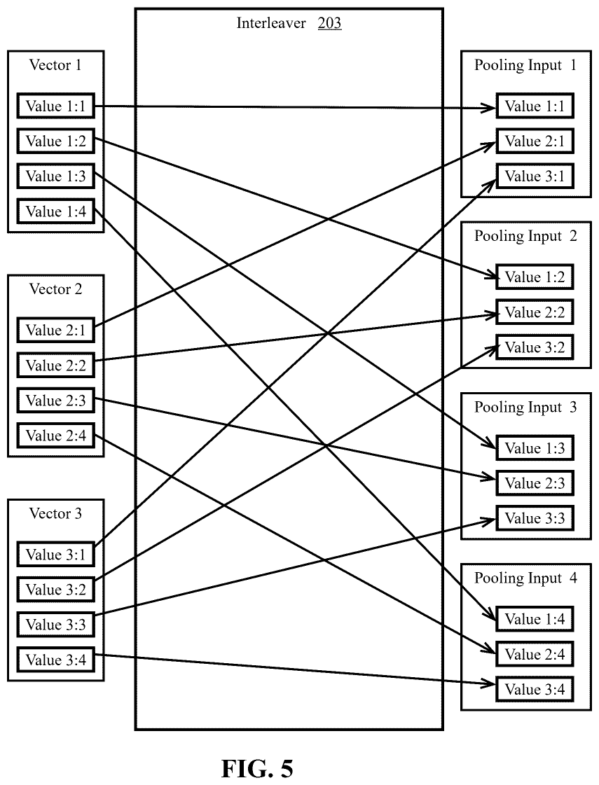

FIG. 5 is a high-level conceptual diagram of an interleaver 203 performing a nonlinear pooling operation, according to some aspects. The interleaver 203 may interleave the representation vectors to produce pooling inputs by placing the ith element of each representation vector into the ith pooling input. As such, B vectors of length Q may result in Q pooling inputs of length B. Each pooling input includes B elements, one from each of the B representation vectors.

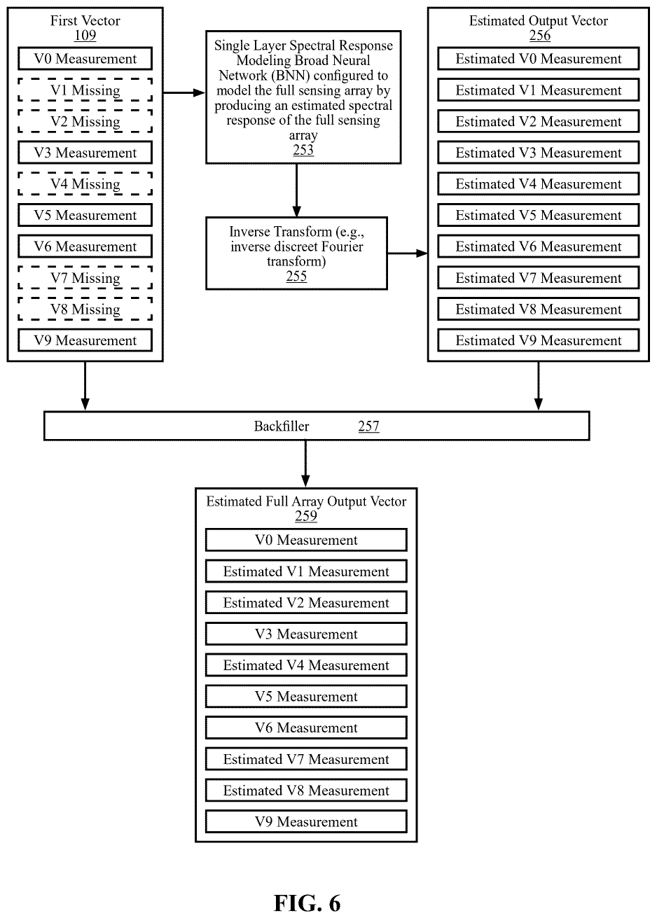

FIG. 6 is a high-level conceptual diagram of a backfiller 257, according to some aspects. A first vector 109 is illustrated that includes measurements for five virtual receivers and that shows five empty slots, indicated by the dash line boxes, for missing measurements. A BNN 253 and an inverse transform function 255 may produce an estimated output vector 256, as discussed above. The estimated output vector 256 includes estimated measurements for the all the virtual receivers of the full sensing array. Some of the estimated measurements correspond to measurements in the first vector 109. For example, the estimated V0 measurement corresponds to the V0 measurement, the estimated V3 measurement corresponds to the V3 measurement, the estimated V5 measurement corresponds to the V5 measurement, the estimated V6 measurement corresponds to the V6 measurement, and the estimated V9 measurement corresponds to the V9 measurement. The backfiller may produce the estimated full array output 259 by copying the measurements in the first vector over the corresponding measurements in the estimated output vector 256.

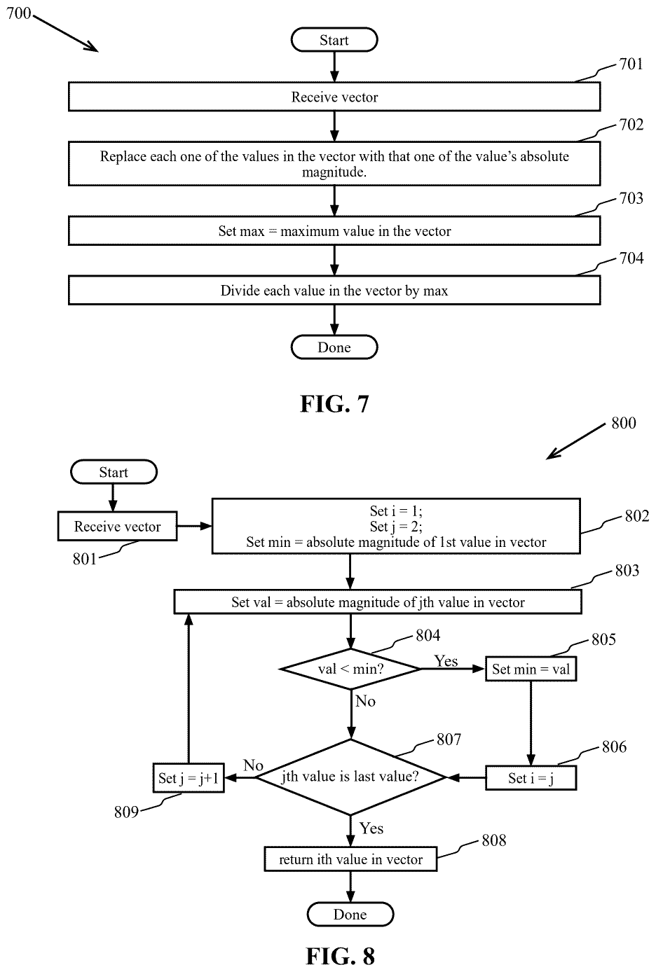

FIG. 7 is a high-level conceptual diagram illustrating an example of normalizing a vector 700, according to some aspects. The example shown in FIG. 7 may be implemented by host machine 301. The vector is received at block 701. At block 702, each one of the values in the vector is replaced with that one of the value's absolute magnitude. At block 703, max is set to equal the value with the maximum magnitude in the vector. At block 704, each value in the vector is divided by max before the process is done.

FIG. 8 is a high-level conceptual diagram illustrating an example of a min-pool nonlinear pooling operation 800, according to some aspects. The example shown in FIG. 8 may be implemented by host machine 301. A vector (e.g., one of the pooling inputs such as first pooling input 241, second pooling input 242, etc.) is received at block 801. At block 802, i is set to 1, j is set to 2, and min is set to the absolute magnitude of the first value in the vector. At block 803 val is set to the absolute magnitude of the jth value in the vector. At decision block 804, val is compared to min. The process moves to block 805 if val is less than min at decision block 804 and otherwise moves to decision block 807. At block 805, min is set to val. At block 806, i is set to j. The process moves to block 808 if the jth value in the vector is the last value in the vector at decision block 807 and otherwise moves to block 809. At block 809, j is incremented by one before the process loops back to block 803. At block 808, the ith value is returned because the ith value is the vector element with the smallest absolute magnitude. The returned value may be stored in the second vector 254 as, for example, a wave domain measurement.

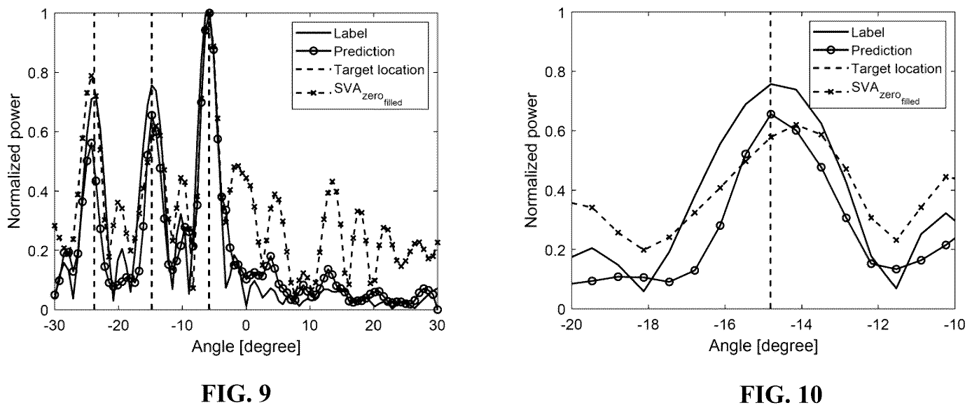

FIG. 9 is a diagram illustrating a graph of an example of predicted target locations relative to actual target locations and to target locations measured by dense and sparse sensing arrays, according to some aspects. Gumbel min pooling was used in the example illustrated in FIG. 9. The results shown in FIG. 9 are simulated results with “Label” indicating the simulated measurement for a dense sensing array that was modeled by a BNN configured to receive a first vector from a sparse virtual array (“SVA”) and to produce a prediction. The simulated output of the SVA is also shown in the graph. As can be seen, the sparse array produced a result with high sidelobes that are suppressed in the BNN output. FIG. 10 is a zoomed in version of FIG. 9, according to some aspects. It appears that the sparse array output is slightly shifted and the BNN prediction is not shifted. Gumbel min pooling has produced an excellent result and may be preferable when the computational cost is acceptable.

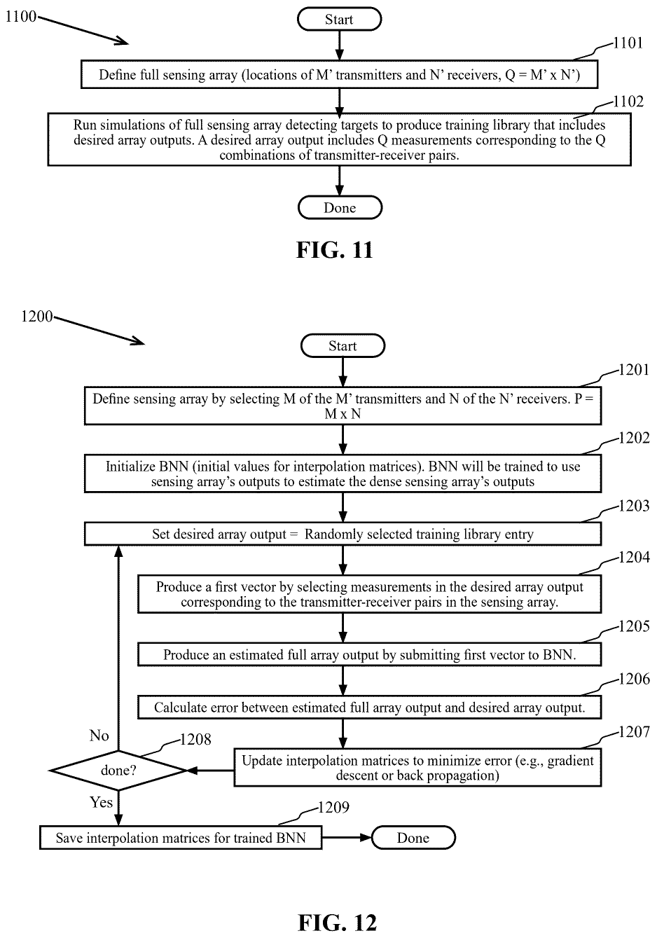

FIG. 11 is a high-level flow diagram illustrating an example of producing a library of desired array outputs 1100 that may be used for training a BNN, according to some aspects. The process illustrated in FIG. 11 may be implemented by host machine 301. At block 1101, the full sensing array is defined by selecting the locations of M′ transmitters and N′ receivers. As such, the dense array has Q=M′×N′ transmitter-receiver pairs and the array response may therefore be a Q element vector. At block 1102, simulations of the dense array detecting targets are run to produce simulated array responses. The simulated array responses are stored in the training library as desired array outputs. Each desired array output includes Q measurements corresponding to the Q combinations of transmitter-receiver pairs. Those practiced in the art of sensing arrays (e.g., RADAR systems) are familiar with running simulations of the sensing arrays.

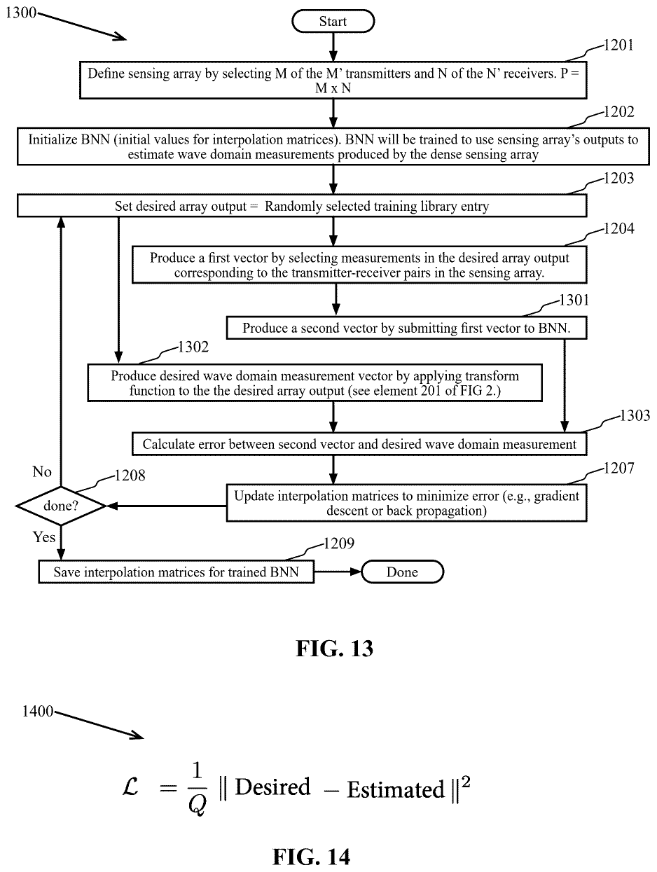

FIG. 12 is a high-level flow diagram illustrating an example of training a BNN that produces an estimated full array output in response to receiving a first vector 1200, according to some aspects. The process illustrated in FIG. 12 may be implemented by host machine 301. At block 1201, the sensing array is defined by selecting M of the transmitters and N of the receivers in the dense array defined at block 1101 in FIG. 11. At block 1202, the BNN is initialized by, for example, writing initial values into the interpolation matrices. The initial values may be randomly generated. The BNN will be trained to use the sensing array's outputs to estimate the dense sensing array's outputs. As such, the BNN may be trained to model a full sensing array that has virtual receivers corresponding to transmitters and receivers that are in the full sensing array and that are missing from the sparse sensing array. At block 1203, one of the desired array outputs is selected from the training library. For example, the desired array output may be a randomly selected training library entry. At block 1204, a first vector is produced by selecting the measurements in the desired array output corresponding to the transmitter-receiver pairs in the sparse sensing array. At block 1205, an estimated full array output is produced by submitting the first vector to the BNN. At block 1206, the error between the estimated full array output and desired array output is calculated. Those practiced in the art know of a variety of loss functions that may be used to calculate the error. At block 1207, the interpolation matrices are updated to minimize the error. As is known in the art, gradient descent and backpropagation are two of the techniques for minimizing the error by updating matrices in neural networks. If training is complete at block 1208, the process moves to block 1209 and otherwise loops back to block 1203. Training may be complete if the error is minimized below a threshold, if a predetermined number of training iterations has been performed, etc. At block 1209, the interpolation matrices are saved such that the trained BNN may be re-instantiated for inferencing or for further training.

FIG. 13 is a high-level flow diagram illustrating an example of training a BNN that produces a wave domain estimate in response to receiving a first vector 1300, according to some aspects. The process illustrated in FIG. 13 may be implemented by host machine 301. The flow diagram in FIG. 13 is similar to the flow diagram shown in FIG. 12. And has many blocks in common. At block 1201, the sensing array is defined by selecting M of the transmitters and N of the receivers in the dense array defined at block 1101 in FIG. 11. At block 1202, the BNN is initialized by, for example, writing initial values into the interpolation matrices. The initial values may be randomly generated. The BNN will be trained to use the sensing array's outputs to estimate the dense sensing array's wave domain response. As such, the BNN may be trained to model a full sensing array that has virtual receivers corresponding to transmitters and receivers that are in the full sensing array and that are missing from the sparse sensing array. At block 1203, one of the desired array outputs is selected from the training library. For example, the desired array output may be a randomly selected training library entry. In FIG. 13, the process moves from block 1203 to block 1204 and to block 1302. At block 1204, a first vector is produced by selecting the measurements in the desired array output corresponding to the transmitter-receiver pairs in the sparse sensing array. At block 1301, a second vector is produced by submitting the first vector to the BNN. At block 1302, the desired wave domain measurement vector is produced by applying the transform function to the desired array output (see transform function 201 of FIG. 2.). At block 1303, the error between the second vector and desired wave domain measurement vector is calculated. Those practiced in the art know of a variety of loss functions that may be used to calculate the error. In FIG. 13, the process moves from block 1303 to block 1207. At block 1207, the interpolation matrices are updated to minimize the error. As is known in the art, gradient descent and backpropagation are two of the techniques for minimizing the error by updating matrices in neural networks. If training is complete at block 1208, the process moves to block 1209 and otherwise loops back to block 1203. Training may be complete if the error is minimized below a threshold, if a predetermined number of training iterations has been performed, etc. At block 1209, the interpolation matrices are saved such that the trained BNN may be re-instantiated for inferencing or for further training.

FIG. 14 is a diagram illustrating an example of a loss function 1400 that may be used to calculate an error between two vectors, according to some aspects. The illustrated likelihood function, in essence, produces a difference vector by subtracting the estimated measurement (e.g., estimated full array output 259, second vector 254, etc.) from the desired measurement. The dot product of the difference vector and its own conjugate may then be calculated to produce a value that is a real number, not a complex number. Dividing that value by Q produces the error.

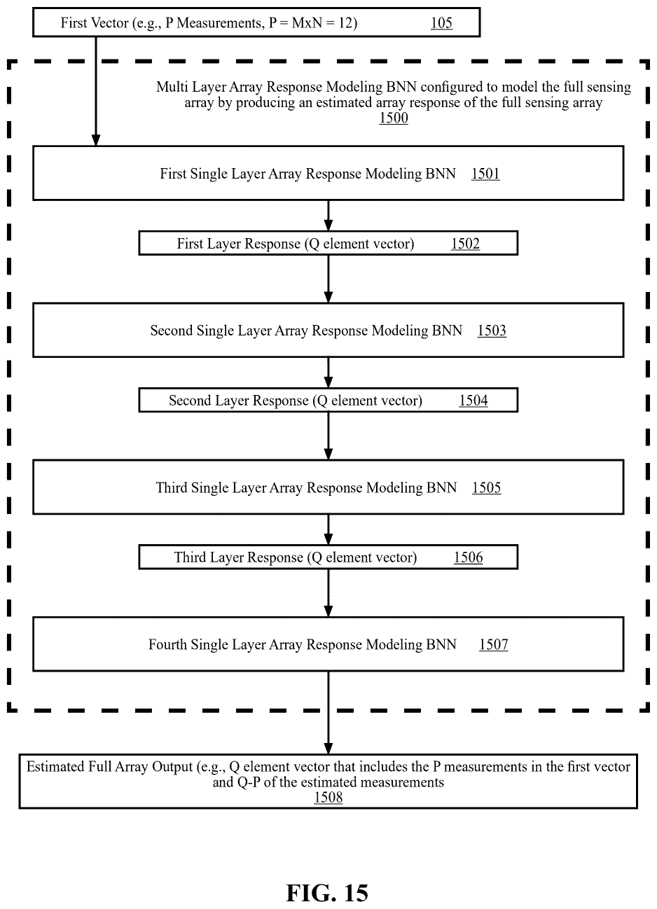

FIG. 15 is a high-level diagram illustrating an example of a multi-layer BNN 1500 configured to produce an estimated full array output 1508 in response to receiving P measurements from a sensing array, according to some aspects. The BNN illustrated in FIG. 15 may be implemented by host machine 301. A first single layer array response modeling BNN 1501 produces a first layer response 1502 in response to receiving the P measurements in a first vector 109. FIG. 1 illustrates an example of a single layer array response modeling BNN. A second single layer array response modeling BNN 1503 produces a second layer response 1504 in response to receiving the first layer response 1502. A third single layer array response modeling BNN 1505 produces a third layer response 1506 in response to receiving the second layer response 1504. A fourth single layer array response modeling BNN 1507 produces the estimated full array output 1508 in response to receiving the third layer response 1506. The multi-layer BNN 1500 may be trained via backpropagation. In an example, a backpropagation algorithm in a machine learning library (e.g., PyTorch, Tensorflow, etc.) updates the interpolation matrices in the single layer BNNs based on an error between the estimated full array output and a desired array output. Referring to FIG. 12, the multi-layer BNN 1500 may produce the estimated full array output at block 1205 and the interpolation matrices of the multi-layer BNN 1500 may be updated at block 1207.

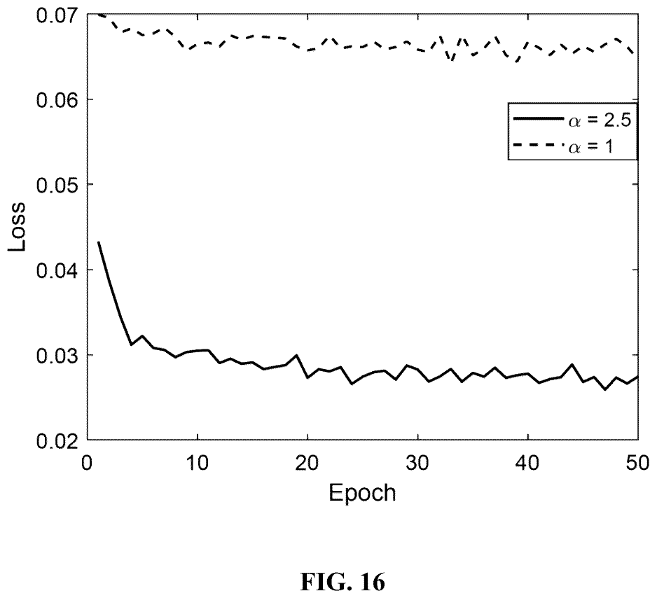

FIG. 16 is a diagram illustrating the training error with respect to different α settings of an iterative backfilling BNN having four layers, according to some aspects. As is known in the art, alpha (α) is a parameter that controls the size of the step taken when updating the weights of a neural network during training, essentially determining how quickly the model learns based on the calculated gradients. A smaller alpha means smaller adjustments to the weights, while a larger alpha leads to faster updates. FIG. 16 illustrates an example in which the loss decreased slowly for an alpha=1 and more quickly for alpha=2.5. As is known in the art, lower values of alpha typically result in slower but more stable training while higher values of alpha may result in faster training but may also result in instabilities that impede training.

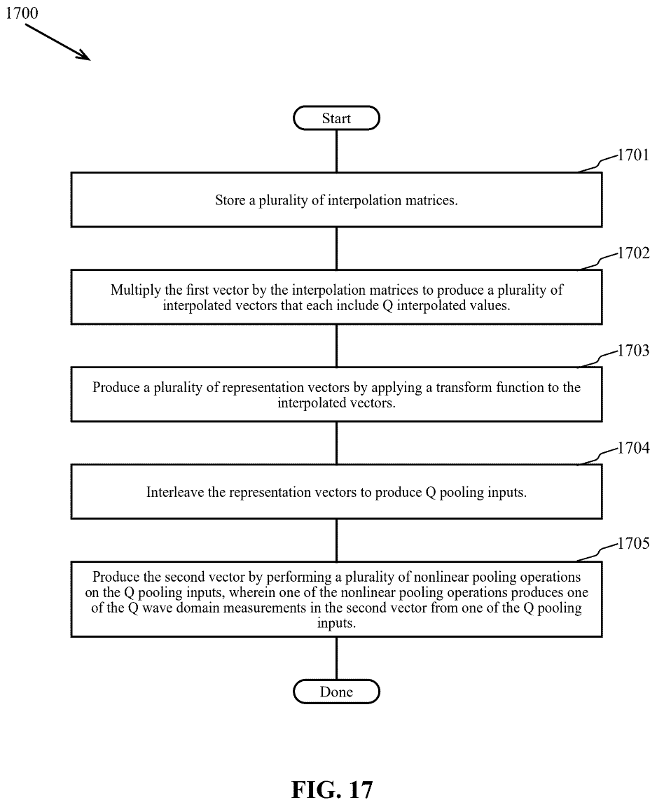

FIG. 17 is a high-level flow diagram illustrating an example of a method that models a full sensing array 1700 by producing a second vector that includes Q wave domain measurements in response to receiving a first vector that includes P measurements produced by a sensing array, according to some aspects. The method illustrated in FIG. 17 may be implemented by host machine 301. At block 1701, a plurality of interpolation matrices may be stored. At block 1702, the first vector may be multiplied by the interpolation matrices to produce a plurality of interpolated vectors that each include Q interpolated values. At block 1703, a plurality of representation vectors may be produced by applying a transform function to the interpolated vectors. At block 1704, an interleaver may interleave the representation vectors to produce Q pooling inputs. At block 1705, the second vector may be produced by performing a plurality of nonlinear pooling operations on the Q pooling inputs, wherein one of the nonlinear pooling operations produces one of the Q wave domain measurements in the second vector from one of the Q pooling inputs.

Aspects described above can be ultimately implemented in devices that include physical circuits that implement digital data processing, storage, and communications. The devices can include processing circuits, ROM, RAM, and at least one interface (interface(s)). The processors (e.g., CPUs or MPUs) described above can be implemented in processing circuits and memory integrated into the same integrated circuit (IC) device as ASIC circuits. For example, processors, such as central processing units, and other semiconductor chip circuits can be fabricated on the same semiconductor substrate to form a System-on-Chip (SoC). The devices may be implemented as single IC devices (e.g., fabricated on a single substrate) or the devices may be implemented as systems that include multiple IC devices connected by, for example, a printed circuit board (PCB). The interfaces may include network interfaces (e.g., Ethernet interfaces) and/or PCIe interfaces. The interfaces may also include other management and control interfaces such as I2C, general purpose IOs, USB, UART, SPI, and eMMC.

Although the operations of the method(s) herein are shown and described in a particular order, the order of the operations of each method may be altered so that certain operations may be performed in an inverse order or so that certain operations may be performed, at least in part, concurrently with other operations. Instructions or sub-operations of distinct operations may be implemented in an intermittent and/or alternating manner.

It should also be noted that at least some of the operations for the methods described herein may be implemented using software instructions stored on a computer usable storage medium for execution by a computer. For example, a computer program product can include a computer usable storage medium to store a computer readable program.

The computer-usable or computer-readable storage medium can be an electronic, magnetic, optical, electromagnetic, infrared, or semiconductor system (or apparatus or device). Examples of non-transitory computer-usable and computer-readable storage media include a semiconductor or solid-state memory, magnetic tape, a removable computer diskette, a random-access memory (RAM), a read-only memory (ROM), a rigid magnetic disk, and an optical disk. Current examples of optical disks include a compact disk with read only memory (CD-ROM), a compact disk with read/write (CD-R/W), and a digital video disk (DVD).

Although specific examples have been described and illustrated, the scope of the claimed systems, methods, devices, etc. is not to be limited to the specific forms or arrangements of parts so described and illustrated. The scope is to be defined by the claims appended hereto and their equivalents.

What is claimed is:

1. A system comprising:
a memory configured to store a plurality of interpolation matrices; and
a processor configured to model a full sensing array by producing a second vector that includes Q wave domain measurements in response to receiving a first vector that includes P measurements produced by a sensing array, wherein producing the second vector includes:
multiplying the first vector by the interpolation matrices to produce a plurality of interpolated vectors that each include Q interpolated values;
producing a plurality of representation vectors by applying a transform function to the interpolated vectors;
interleaving the representation vectors to produce Q pooling inputs; and
producing the second vector by performing a plurality of nonlinear pooling operations on the Q pooling inputs, wherein one of the nonlinear pooling operations produces one of the Q wave domain measurements in the second vector from one of the Q pooling inputs.

2. The system of claim 1, wherein an ith one of the Q pooling inputs includes an ith element of each of the representation vectors.

3. The system of claim 1, wherein each of the representation vectors is normalized before the Q pooling inputs are produced.

4. The system of claim 1, wherein:
the plurality of interpolation matrices includes B interpolation matrices;
the plurality of interpolated vectors includes B interpolated vectors produced by multiplying the first vector by each of the B interpolation matrices; and
the plurality of representation vectors includes B representation vectors produced by applying the transform function to the B interpolation matrices.

5. The system of claim 1, wherein the transform function is a discrete Fourier transform.

6. The system of claim 1, wherein the transform function is a linear transform.

7. The system of claim 1, wherein:
the one of the Q pooling inputs includes a plurality of wave domain values; and
the one of the nonlinear pooling operations selects the one of the wave domain values having a smallest absolute magnitude as the one of the Q wave domain measurements.

8. The system of claim 1, wherein the processor is further configured to model the full sensing array by producing an estimated full array output that includes the P measurements and that includes at least one of a plurality of estimated measurements by:
producing the plurality of estimated measurements by applying an inverse transform function to the Q wave domain measurements;
identifying P of the estimated measurements that correspond to the P measurements; and
producing the estimated full array output, the estimated full array output including the P measurements, at least one of the estimated measurements, and none of the P of the estimated measurements that correspond to the P measurements.

9. The system of claim 1, wherein:
a plurality of simulations of the full sensing array produces a plurality of desired array outputs that are used to produce a plurality of desired second vectors;
the desired array outputs are used to produce a plurality of simulated first vectors that are used to produce a plurality of simulated second vectors; and
the interpolation matrices are produced by minimizing a plurality of errors between the desired second vectors and the simulated second vectors.

10. A method that models a full sensing array by producing a second vector that includes Q wave domain measurements in response to receiving a first vector that includes P measurements produced by a sensing array, the method including:
storing a plurality of interpolation matrices;
multiplying the first vector by the interpolation matrices to produce a plurality of interpolated vectors that each include Q interpolated values;
producing a plurality of representation vectors by applying a transform function to the interpolated vectors;
interleaving the representation vectors to produce Q pooling inputs; and
producing the second vector by performing a plurality of nonlinear pooling operations on the Q pooling inputs, wherein one of the nonlinear pooling operations produces one of the Q wave domain measurements in the second vector from one of the Q pooling inputs.

11. The method of claim 10, wherein an ith one of the Q pooling inputs includes an ith element of each of the representation vectors.

12. The method of claim 10, wherein each of the representation vectors is normalized before the Q pooling inputs are produced.

13. The method of claim 10, wherein:
the plurality of interpolation matrices includes B interpolation matrices;
the plurality of interpolated vectors includes B interpolated vectors produced by multiplying the first vector by each of the B interpolation matrices; and
the plurality of representation vectors includes B representation vectors produced by applying the transform function to the B interpolation matrices.

14. The method of claim 10, wherein the transform function is a discrete Fourier transform.

15. The method of claim 10, further including:
producing a plurality of estimated measurements by applying an inverse transform function to the Q wave domain measurements;
identifying P of the estimated measurements that correspond to the P measurements; and
producing an estimated full array output of the full sensing array, the estimated full array output including the P measurements, at least one of the estimated measurements, and none of the P of the estimated measurements that correspond to the P measurements.

16. A system comprising:
a memory configured to store a plurality of transformative matrices; and
a processor configured to model a full sensing array by producing a second vector that includes Q wave domain measurements in response to receiving a first vector that includes P measurements produced by a sensing array, wherein producing the second vector includes:
multiplying the first vector by the transformative matrices to produce a plurality of representation vectors;
interleaving the representation vectors to produce Q pooling inputs; and
producing the second vector by performing a plurality of nonlinear pooling operations on the Q pooling inputs, wherein one of the nonlinear pooling operations produces one of the Q wave domain measurements in the second vector from one of the Q pooling inputs.

17. The system of claim 16, wherein each one of the transformative matrices is a linear product of one of a plurality of interpolation matrices and a linear transform matrix.

18. The system of claim 17, wherein the linear transform matrix is a discrete Fourier transform matrix.

19. The system of claim 16, wherein:
multiplying the transformative matrices by an inverse linear transform matrix produces a plurality of interpolation matrices.

20. The system of claim 16, wherein:
a plurality of simulations of the full sensing array produces a plurality of desired array outputs that are used to produce a plurality of desired second vectors;
the desired array outputs are used to produce a plurality of simulated first vectors that are used to produce a plurality of simulated second vectors;
a plurality of interpolation matrices is produced by minimizing a plurality of errors between the desired second vectors and the simulated second vectors; and
the transformative matrices are produced by multiplying the plurality of interpolation matrices by a linear transform matrix.
